(19) United States
(12) Patent Application Publication
(10) Pub. No.: US 2025/0243578 A1
(43) Pub. Date: Jul. 31, 2025

(54) Mask and Preparation Method Thereof

(71) Applicant: BOE Technology Group Co., Ltd., Beijing (CN)

(72) Inventors: Lu WANG, Beijing (CN); Dacheng ZHANG, Beijing (CN); Dejiang ZHAO, Beijing (CN); Weijie WANG, Beijing (CN); Zhiqiang JIAO, Beijing (CN)

(21) Appl. No.: 18/694,440

(22) PCT Filed: Jul. 21, 2023
(86) PCT No.: PCT/CN2023/108617

§ 371 Date: Mar. 22, 2024

(30) Foreign Application Priority Data
Apr. 7, 2023 (CN) 202310368507.1

(51) Int. Cl. C23C 14/04

(52) U.S. Cl. CPC C23C 14/042

(57) ABSTRACT

A mask and a preparation method thereof are provided. The mask comprises: a first region (100) comprising a first shield structure (110) and a plurality of hollows (120), an orthographic projection of the first shield structure (110) in the first region (100) surrounding an orthographic projection of the hollows (120) in the first region (100), the first shield structure (110) being configured to form a mask pattern; and a second region (200) surrounding the first region (100), the second region (200) comprising a second shield structure (210); wherein a side surface of the first shielding structure (110) in a thickness direction comprises at least one first convex part (a1) and at least one first concave part (b1), the first convex part (a1) are connected with the first concave part (b1); the first shielding structure (110) comprises a metal layer and the second shielding structure (210) comprises a silicon-containing material layer.

### CROSS-REFERENCE TO RELATED APPLICATIONS

The present application is a U.S. National Phase Entry of International Application No. PCT/CN2023/108617, having an international filing date of Jul. 21, 2023, which claims priority of Chinese Patent Application No. 202310368507.1, filed to the CNIPA on Apr. 7, 2023 and entitled “Mask and Preparation Method thereof”. The entire contents of above-identified applications are hereby incorporated by reference.

### TECHNICAL FIELD

Embodiments of the present disclosure relate to, but are not limited to, the technical field of thin films, in particular to a mask and a preparation method thereof.

### BACKGROUND

At present, in the preparation process of display panels, a mask needs to be attached together with a target process object, which may be the substrate in the preparation process of display panels. Under the action of gravity droop, the distance between some masks and the target process object changes, which seriously affects the precision of the graphic structure prepared on the target process object and finally affects the product quality of a display panel.

### SUMMARY

The following is a summary of subject matter described herein in detail. The summary is not intended to limit the scope of protection of the claims.

Embodiments of the present disclosure provide a mask and a preparation method thereof.

In a first aspect, an embodiment of the present disclosure provides a mask, comprising:
a first region comprising a first shield structure and a plurality of hollows, an orthographic projection of the first shield structure in the first region surrounding an orthographic projection of the hollows in the first region, and the first shield structure being configured to form a mask pattern; and
a second region surrounding the first region, the second region comprising a second shield structure;
wherein, a side surface of the first shield structure in a thickness direction comprises at least one first convex part and at least one first concave part, and the first convex part is connected with the first concave part;
the first shield structure comprises a metal layer, and the second shield structure comprises a silicon-containing material layer.

In some implementations, in a direction perpendicular to the thickness direction of the first shield structure, in the first convex part and the first concave part adjacent to each other, the size of the first shield structure corresponding to the position of the first convex part is larger than the size of the first shield structure corresponding to the position of the first concave part.

The curvature of the first convex part is smaller than the curvature of the first concave part.

In some implementations, the first shield structure comprises a first substructure, the second shield structure comprises a second substructure, the first substructure is the first shield structure closest to a boundary between the first region and the second region, and a side surface of the second substructure in the thickness direction is connected with a side surface of the first substructure in the thickness direction.

The side surface of the second substructure in the thickness direction comprises at least one second convex part and at least one second concave part, the shape of the second convex part is matched with the shape of the first concave part, the shape of the second concave part is matched with the shape of the first convex part, and the curvature of the second concave part is smaller than the curvature of the second convex part.

In some implementations, the thickness of the first substructure is the same as that of the second substructure.

In some implementations, the mask is configured to form a patterned structure on a target process object using the mask pattern formed by the first shield structure, and a side of the mask close to the target process object is a process side.

The first shield structure satisfies at least one of the following conditions: a surface of the first shield structure on a side away from the process side is coplanar with a surface of the second substructure on a side away from the process side; and, a surface of the first shield structure on a side close to the process side is coplanar with a surface of the second substructure on a side close to the process side.

In some implementations, the first shield structure comprises a first substructure, the second shield structure comprises a third substructure, the first substructure is the first shield structure closest to a boundary between the first region and the second region, and the first substructure and the third substructure are stacked in the thickness direction.

A side surface of the first shield structure has a first slope angle, the first slope angle is an included angle between the plane formed by all of the raised vertices of the first convex parts and the contact interface of the first substructure and the third substructure.

A side surface of the third substructure in the thickness direction has a second slope angle, the second slope angle is an included angle between the side surface of the third substructure in the thickness direction and the contact interface of the first substructure and the third substructure.

The first slope angle and the second slope angle are both acute angles, and the first slope angle is larger than the second slope angle.

In some implementations, a surface of the first shield structure on a side close to the third substructure is coplanar with a surface of the third substructure on a side close to the first substructure.

In some implementations, a surface of the first substructure on a side close to the third substructure is connected in a bonding manner with a surface of the third substructure on a side close to the first substructure.

In some implementations, the mask satisfies one or more of the following conditions:
the metal layer comprises a magnetically attractive metal material;
the first shield structure comprises the silicon-containing material layer and the silicon-containing material layer comprises at least one of a monocrystalline silicon wafer and a silicon compound layer;
and, the second shield structure comprises the magnetically attractive metal material.

In some implementations, in a case where the first shield structure comprises a magnetically attractive metal layer and a first silicon-containing material layer, the magnetically attractive metal layer is close to the process side, and the first silicon-containing material layer is away from the process side with respect to the magnetically attractive metal layer.

In some implementations, the mask satisfies one or more of the following conditions:
the thickness of the magnetically attractive metal layer is smaller than the inner diameter of the hollows;
the thickness of the magnetically attractive metal layer is less than or equal to 10 um;
in a case where the side surface of the first shield structure has a first slope angle, the difference between the first slope angle corresponding to the magnetically attractive metal layer and the first slope angle corresponding to the first silicon-containing material layer is less than or equal to 5°;
the first silicon-containing material layer and the second shield structure belong to different substrates;
in a case where the first silicon-containing material layer comprises a first monocrystalline silicon wafer, the thickness of the first monocrystalline silicon wafer is less than or equal to 20 μm;
and, in a case where the second shield structure comprises a second monocrystalline silicon wafer, the thickness of the second monocrystalline silicon wafer is greater than or equal to 100 μm.

In some implementations, in a case where the first shield structure comprises a first substructure and the second shield structure comprises a second substructure, the second shield structure comprises a third substructure, the first substructure and the third substructure are stacked in the thickness direction.

The second substructure comprises a first monocrystalline silicon wafer, and the third substructure comprises a first silicon compound layer, a second monocrystalline silicon wafer, and a second silicon compound layer.

The first monocrystalline silicon wafer and the first silicon compound layer belong to the same substrate, and the second monocrystalline silicon wafer and the second silicon compound layer belong to the same substrate.

The first silicon compound layer is connected with the second silicon compound layer in a bonding manner, the first monocrystalline silicon wafer is located on a side of the first silicon compound layer away from the second silicon compound layer, and the second monocrystalline silicon wafer is located on a side of the second silicon compound layer away from the first silicon compound layer.

In some implementations, a side surface of the second silicon compound layer in the thickness direction are parallel to a side surface of the second monocrystalline silicon wafer in the thickness direction.

In a second aspect, an embodiment of the present disclosure provides a preparation method of a mask, comprising:
etching a side of a substrate to obtain a plurality of grooves, wherein the substrate comprises a first region and a second region, the second region surrounds the first region, and the substrate comprises a silicon-containing material layer, wherein sidewalls of the grooves in a depth direction comprise at least one third concave part and at least one third convex part, and the third concave part is connected with the third convex part;
arranging a metal layer on a side of the substrate with the grooves, so that the grooves are filled with the metal layer; and
etching the substrate of the first region to obtain a plurality of hollows, so that the metal layer forms a first shield structure, and the substrate of the second region forms a second shield structure, wherein, an orthographic projection of the first shield structure in the first region surrounds an orthographic projection of the hollows in the first region, the first shield structure is configured to form a mask pattern, a side surface of the first shield structure in a thickness direction comprises at least one first convex part and at least one first concave part, the first convex part is connected with the first concave part, the first convex part has the same shape with the third concave part, and the first concave part has the same shape with the third convex part.

In some implementations, the substrate comprises a monocrystalline silicon wafer.

Before the etching the substrate of the first region, the preparation method further comprises:
chemically mechanical grinding the substrate on a side arranged with the metal layer to remove the metal layer between openings of the adjacent grooves, and controlling the thickness of the metal layer in the grooves to reach a given thickness;
arranging a silicon compound layer on a surface of the substrate; and
etching the silicon compound layer on a side away from the metal layer to obtain at least one first opening, wherein an orthographic projection of the first opening on the substrate covers the first region.

The etching the substrate of the first region comprises:
etching the silicon compound layer on a side close to the metal layer to obtain at least one second opening, wherein an orthographic projection of the second opening on the substrate covers the first region; and
through the first opening and the second opening, etching the substrate of the first region to obtain a plurality of hollows, so that the metal layer forms the first shield structure, and the substrate of the second region forms the second shield structure.

In some implementations, the etching a side of the substrate to obtain a plurality of grooves comprises:
etching a side of the first substrate to obtain a plurality of grooves.

Before the etching the substrate of the first region to obtain a plurality of hollows, the preparation method further comprises:
arranging a second silicon compound layer on an outer surface of the second substrate;
etching the second silicon compound layer on a side of the second substrate to obtain at least one third opening, wherein an orthographic projection of the third opening on the second substrate covers the first region; and
connecting a surface of the first substrate on a side arranged with the metal layer in a bonding manner with a surface of the second substrate on a side away from the third opening, to obtain a third substrate.

The etching the substrate of the first region to obtain a plurality of hollows comprises:
chemically mechanical grinding the third substrate on a side arranged with the metal layer to remove the metal layer between openings of the adjacent grooves, and controlling the thickness of the metal layer in the grooves to reach a given thickness;
etching the first substrate outside the metal layer of the first region to obtain a plurality of first hollows, wherein the metal layer surrounds the first hollows; and
through the third opening, etching the second substrate of the first region to obtain at least one second hollow, wherein the second hollow is communicated with the first hollow, and the second hollow is in one-to-one correspondence with the third opening.

In some implementations, before connecting a surface of the first substrate on a side arranged with the metal layer in a bonding manner with a surface of the second substrate on a side away from the third opening to obtain the third substrate, the preparation method further comprises: arranging a first silicon compound layer on an outer surface of the first substrate; and/or,
the arranging a second silicon compound layer on an outer surface of the second substrate comprises: arranging the second silicon compound layer on a side surface of the second substrate.

In some implementations, before the etching a side of the substrate to obtain a plurality of grooves, the preparation method further comprises:
arranging a third silicon compound layer on an outer surface of the substrate; and/or,
the arranging the metal layer comprises: arranging a seed layer; electroplating the metal layer on the seed layer.

In some implementations, the etching a side of the substrate to obtain a plurality of grooves comprises:
performing a first etching on a side of the substrate to obtain a plurality of first grooves;
performing a first passivation treatment on the inner walls of the first grooves; and
sequentially performing a second etching treatment and a second passivation treatment of the first grooves having been performed the first passivation treatment, until a plurality of grooves with given depths are obtained, wherein the sidewalls of the grooves in the depth direction comprise at least one third concave part and at least one third convex part, and the inner diameter of the grooves corresponding to the position of the third concave part is larger than the inner diameter of the grooves corresponding to the position of the third convex part.

In a third aspect, an embodiment of the present disclosure provides a preparation method of a mask, comprising:
arranging a metal layer on a side of a substrate, wherein the substrate comprises a first region and a second region, the second region surrounds the first region, and the substrate comprises a silicon-containing material layer;
etching the metal layer of the first region to obtain a plurality of first hollows, wherein the metal layer between the first hollows forms a first shield structure, and the first shield structure is configured to form a mask pattern; and
etching the substrate of the first region to obtain at least two second hollows, so that the second hollows are communicated with the first hollows, wherein the substrate of the second region forms a second shield structure.

Other features and advantages of the present disclosure will be set forth in the following specification, and moreover, partially become apparent from the specification, or are understood by implementing the present disclosure. Other advantages of the present disclosure may be achieved and obtained through solutions described in the specification and drawings.

Other aspects of the present disclosure may be comprehended after the drawings and the detailed descriptions are read and understood.

### BRIEF DESCRIPTION OF DRAWINGS

The accompanying drawings are intended to provide an understanding of technical schemes of the present application and form a part of the specification, and are used to explain the technical schemes of the present disclosure together with embodiments of the present disclosure, and not intended to form limitations to the technical schemes of the present disclosure. Shapes and sizes of components in the drawings do not reflect actual scales, and are only intended to schematically illustrate contents of the present disclosure.

FIG. 1 is a schematic diagram of the cross-sectional structure of a mask provided by an embodiment of the present disclosure.

FIG. 2 is a schematic diagram of the planar structure of a mask provided by an embodiment of the present disclosure.

FIG. 3 is a schematic diagram of the planar structure of another mask provided by an embodiment of the present disclosure.

FIG. 4 is a schematic diagram of the positional relationships between the mask shown in FIG. 1 and a target process object.

FIG. 5 is a schematic diagram of the cross-sectional structure of another mask provided by an embodiment of the present disclosure.

FIG. 6 is a schematic diagram of the cross-sectional structure of yet another mask provided by an embodiment of the present disclosure.

FIG. 7 is an exemplary flow diagram of a preparation method of a mask provided by an embodiment of the present disclosure.

FIG. 8 is an exemplary flow diagram of an etching process of a groove provided by an embodiment of the present disclosure.

FIG. 9 is an exemplary first process flow diagram of a preparation method of a mask provided by an embodiment of the present disclosure.

FIG. 10 is an exemplary second process flow diagram of a preparation method of a mask provided by an embodiment of the present disclosure.

FIG. 11 is an exemplary third process flow diagram of a preparation method of a mask provided by an embodiment of the present disclosure.

FIG. 12 is an exemplary fourth process flow diagram of a preparation method of a mask provided by an embodiment of the present disclosure.

FIG. 13 is an exemplary fifth process flow diagram of a preparation method of a mask provided by an embodiment of the present disclosure.

FIG. 14 is an exemplary sixth process flow diagram of a preparation method of a mask provided by an embodiment of the present disclosure.

FIG. 15 is an exemplary seventh process flow diagram of a preparation method of a mask provided by an embodiment of the present disclosure.

FIG. 16 is an exemplary eighth process flow diagram of a preparation method of a mask provided by an embodiment of the present disclosure.

FIG. 17 is an exemplary flow diagram of a preparation method of another mask provided by an embodiment of the present disclosure.

FIG. 18 is an exemplary ninth process flow diagram of a preparation method of a mask provided by an embodiment of the present disclosure.

FIG. 19 is an exemplary tenth process flow diagram of a preparation method of a mask provided by an embodiment of the present disclosure.

### DETAILED DESCRIPTION

In order to better understand the technical schemes provided by the embodiments of the present specification, the technical schemes of the embodiments of the present specification are described in detail below through the drawings and exemplary embodiments. It should be understood that the embodiments of the present specification and the features in the embodiments are a detailed description of the technical schemes of the embodiments of the present specification, not a limitation of the technical schemes of the present specification, and the embodiments of the present specification and the technical features in the embodiments can be combined with each other if there is no conflict.

Relational terms such as first and second are used herein only to distinguish one entity or operation from another and do not necessarily require or imply any such actual relationship or order between these entities or operations. Moreover, the terms “include”, “comprise” or any other variations thereof are intended to cover a non-exclusive inclusion, such that a process, method, article, or device that includes a series of elements includes not only those elements but also other elements which are not expressly listed, or further includes elements inherent to such a process, method, article, or device. Without more limitations, an element modified by “include one . . . ” does not exclude that the process, method, object, or device that includes the element includes another identical element. The term “two or more” includes the cases of two or more.

In the preparation process of display panels, a mask may be attached together with a target process object, which may be the substrate in the preparation process of display panels. Under the action of gravity droop, the distance between some masks and the target process object would change, which seriously affects the precision of the graphic structure prepared on the target process object and finally affects the product quality of a display panel. At present, in order to realize the preparation of pixel structure graphs of high resolution, the commonly used masks are prepared from silicon material in the preparation process of display panels. However, the existing mask of silicon material is difficult to resist gravity droop effect by using other contactless external forces except supporting or clamping.

An embodiment of the present disclosure provides a mask and a preparation method thereof. By arranging a metal layer in a first shield structure of the mask for forming a mask pattern, the mask is enabled to resist gravity droop effect through magnetic attraction force, thereby ensuring the preparation precision of the graphic structure on a display panel and further improving the product quality of the display panel.

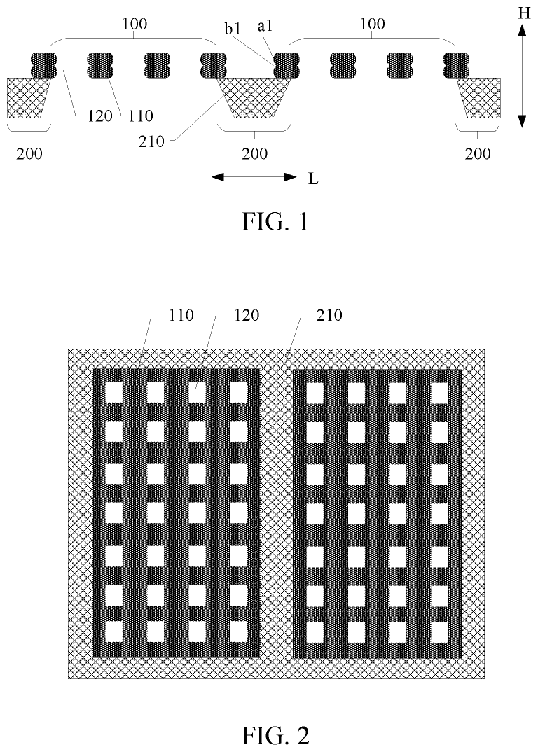

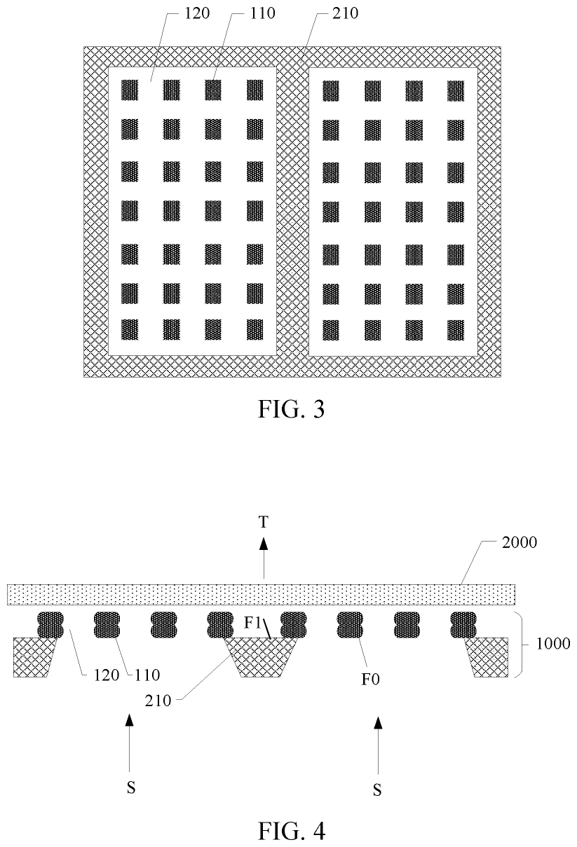

Exemplary embodiments of the present disclosure provide a mask. FIG. 1 is a schematic diagram of the cross-sectional structure of a mask provided by an embodiment of the present disclosure; FIG. 2 is a schematic diagram of the planar structure of a mask provided by an embodiment of the present disclosure; and FIG. 3 is a schematic diagram of the planar structure of yet another mask provided by an embodiment of the present disclosure. As shown in FIGS. 1-3, the mask provided by the exemplary embodiments of the present disclosure may comprise: a first region 100 and a second region 200 with the second region 200 surrounding the first region 100. The first region 100 may comprise a first shield structure 110 and a plurality of hollows 120. An orthographic projection of the first shield structure 110 in the first region 100 surrounds an orthographic projection of the hollows 120 in the first region 100. The first shield structure 110 is configured to form a mask pattern. The side surface of the first shield structure 110 in the thickness direction H may comprise: at least one first convex part a1 and at least one first concave part b1. The first convex part a1 is connected with the first concave part b1. The first shield structure 110 may comprise a metal layer. The second region 200 may comprise a second shield structure 210 which may comprise a silicon-containing material layer. Here, the number, shape and arrangement of the hollows 120 shown in FIGS. 1-3 are all schematic, the number, shape and arrangement of the first convex part a1 and the first concave part b1 shown in FIGS. 1-3 are all schematic, and the embodiments of the present disclosure are not limited thereto.

In some implementations, the silicon-containing material layer may comprise at least one of a monocrystalline silicon wafer and a silicon compound layer.

In some implementations, the metal layer may be a film layer formed of a metallic material capable of being magnetically attracted. For example, it may be a film layer comprising a metallic material such as an alloy containing iron and nickel, metallic iron, or metallic nickel, etc. What generates the magnetic force may be a magnet or the action of a magnetic field converted from electric energy, which is not limited herein in the embodiments of the present disclosure.

In some implementations, the first shield structure 110 can be formed by arranging grooves on the silicon-containing material layer, filling a metal layer in the grooves, removing the silicon-containing material layer between the grooves and then retaining the structure of the metal layer, so that the metal layer can form the first shield structure 110. Exemplarily, the hollows 120 between the first shield structures 110 may be penetrating and may form a mask pattern. Exemplarily, the concave-convex structure on the side surface of the first shield structure 110 (including the first convex part a1 and the first concave part b1) may be a concave-convex structure formed from the inner walls of the grooves. Thus, in order to form the concave-convex structure on the side surface of the first shield structure 110, the inner walls of the grooves may be set in an unsmooth state during the arranging of the grooves on the silicon-containing material layer, so that the inner walls of the grooves have the concave-convex structure, and thereby, the side surface of the metal layer filled in the grooves correspondingly has the concave-convex structure. Exemplarily, the concave-convex structure on the side surface of the first shield structure 110 may match with the concave-convex structure of the inner walls of the grooves, that is, the convex part of the sidewalls of the grooves may correspondingly form the concave part of the side surface of the first shield structure in the thickness direction H (e.g. the first concave part b1), and the concave part of the inner walls of the grooves may correspondingly form the convex part of the side surface of the first shield structure in the thickness direction H (e.g. the first convex part a1).

In some implementations, in thin film technology, a mask may be used to prepare a graphic structure on a target process object. For example, in the preparation process of a display panel, a gate structure may be prepared on a base substrate. Since the gate structures are arranged in an array and the gate structures of pixels in different rows or columns are independent, the process of preparing the gate structure may comprise: arranging a gate film layer on the base substrate, etching the gate film layer to obtain a plurality of gate structures, and alternatively, before the etching, transferring the pattern of the gate structure onto a pre-coated photoresist. Exposure and development may be used in the process of pattern transfer, and the exposure process may use the mask for illumination.

In other implementations, hollows or high-transmittance setting may be provided in a light-irradiable area of the mask. For example, in the preparation process of organic light-emitting display panel, the organic light-emitting layer is usually arranged by evaporation process. A mask may be used in the evaporation process to shield the area where the evaporation is not required, and the hollows may be arranged on the mask to carry out material transmission evaporation on the area where the evaporation is required.

The structures of the first shield structure 110 of the two types of masks illustrated in FIG. 2 and FIG. 3 are complementary. In practical applications, those skilled in the art may set the shapes of the first shield structure 110 according to different patterning requirements. The patterns formed by the first shield structure 110 are mask patterns, and the patterns of the hollows 120 may be patterns required by evaporated organic light-emitting layers. The second shield structure 210 may be configured as serving as a frame supporting the entire mask and may be configured as a fixed support or clamp during the process.

Exemplarily, as shown in FIG. 2, the shape of the hollows 120 may be rectangular or may be any other shapes such as a polygon or the like, which is not limited herein in the embodiments of the present disclosure.

Exemplarily, as shown in FIG. 3, the shape of the first shield structure 110 may be rectangular or may be any other shapes such as a polygon or the like, which is not limited herein in the embodiments of the present disclosure.

A Fine Metal mask (FMM) is used in the usual evaporation of a mask, which is generally made of metal materials. The traditional metal mask is prepared by etching hollows in metal materials. Because the etching precision is limited by etching equipments, and especially the thickness of metal materials itself is relatively thick, the etching equipments usually have low precision in etching thicker metals. Therefore, when making a mask with metal materials, the pixel resolution (Pixels Per Inch, PPI) that generally can be made is generally around 600. When a mask is made by electroforming, PPI can be increased to 800 to 100, but it is hard to make another breakthrough. Therefore, in order to realize the preparation of pixel structure graphs of high resolution, silicon material can be used to prepare masks in the preparation process of display panels.

Theoretically, a mask can be directly made from silicon materials (such as silicon wafers), and the thickness of a mask can be reduced to 20 μm or less. Moreover, the mask of silicon materials has good rigidity, and in the size of 50 mm to 100 mm, it can raise the PPI to 5000 or more, which is very suitable to the application in Augmented Reality (AR), Virtual Reality (VR) and other products. However, in fact, because silicon materials (such as silicon wafers) themselves have no magnetism and cannot be adsorbed, a droop problem will occur under the action of gravity. Moreover, a tiny droop of the mask will lead to the increase of shadows, which makes the evaporation area exceed the predetermined range and leads to leakage between devices. In the evaporation process, a mask is usually attached together with a target process object, so that the evaporation source material is adhered to the target process object through hollows to form a convex structure. Usually, a mask is fixed by clamping or supporting force, and the position where the supporting and clamping are usually applied is the position of the second shield structure, that is, around or in the middle of the mask. Then, due to the action of gravity droop, the local droop of the mask in the unsupported or unclamped areas will make the distance between the mask and the target process object uneven, which will lead to a precision decrease of the graphic structure formed on the target process object corresponding to the droop position, and further affect the product quality.

Therefore, in the mask provided by an embodiment of the present disclosure, a metal layer is arranged in the first shield structure 110, and a silicon-containing material layer is arranged in the second shield structure 210, so that the micropore structure of the mask is made of metal material, and the second shield structure for supporting is made of silicon material. The process of the silicon mask can be combined with the electroforming process, that is, grooves can be arranged on the silicon-containing material layer first, and a concave-convex sidewall can be formed during the groove arranging. The metal material is filled into the grooves, and then the silicon-containing material layer between the grooves is removed, so that the first shield structure 110 formed by the metal layer can be obtained. The side surface of the first shield structure 110 will form the first convex part a1 and the first concave part b1. In this way, the thickness of the silicon-containing material layer etched can be controlled to be thinner, and the precision of etching the thinner silicon-containing material layer is higher than that of etching the thicker metal, so that the density of hollows on the obtained first shield structure is higher, and the resolution of the obtained mask pattern is higher. In addition, the metal layer combined with the mask can be adsorbed by magnetic attraction, so that the mask can be attached to the target process object under the action of magnetic attraction on the basis of improving the resolution of the mask, and can resist the gravity droop effect. In addition, the first shield structure 110 is the bulk micropore structure of the mask, the area of the mask occupied by the first shield structure 110 is larger than that occupied by the second shield structure 210, and then, the area of the mask occupied by the metal layer is larger than that occupied by the second shield structure 210. In the manufacturing process of a mask, compared with supporting or clamping the second shield structure 210, the fixing uniformity and fixing strength of the metal layer under the action of magnetic attraction are stronger, which can ensure the uniformity of the attaching distance between the mask and the target process object and have better resistance to the gravity droop effect.

In some implementations, as shown in FIG. 1, in the direction perpendicular to the thickness direction H of the first shield structure 110, in the first convex part a1 and the first concave part b1 adjacent to each other, the size of the first shield structure 110 corresponding to the position of the first convex part a1 is larger than the size of the first shield structure 110 corresponding to the position of the first concave part b1. For example, as shown in FIG. 1, the H direction is the thickness direction perpendicular to the first shield structure 110, and the H direction and the L direction are perpendicular to each other, that is, the L direction is a direction perpendicular to the H direction. Then, in the first convex part a1 and the first concave part b1 adjacent to each other in the H direction, the size of the first shield structure 110 corresponding to the position of the first convex part a1 is larger than the size of the first shield structure 110 corresponding to the position of the first concave part b1, which may be understood as that: the width of the first shield structure 110 corresponding to the first convex part a1 is larger than the width of the first shield structure 110 corresponding to the first concave part b1, wherein the width of the first shield structure 110 may refer to the dimensions of the first shield structure 110 along the L direction. The curvature of the first convex part a1 is smaller than the curvature of the first concave part b1, and then the radius of curvature of the first convex part a1 is larger than the radius of curvature of the first concave part b1.

Exemplarily, the curvatures of the first convex part a1 and the first concave part b1 may be determined by the etching mode and etching process parameters of the groove etching. The first shield structure 110 having the first convex part a1 and the first concave part b1 may be formed correspondingly by filling a metal layer into the grooves.

In some implementations, FIG. 4 is a schematic diagram of the positional relationships between the mask shown in FIG. 1 and a target process object. As shown in FIG. 4, taking the evaporation process in which the mask provided by an embodiment of the present disclosure is applied to the organic light-emitting layer of a display panel as an example, the target process object may be a substrate 2000 in the preparation process of the display panel, the mask 1000 is arranged opposite to the substrate 2000 of the display panel, and the evaporation source S reaches the substrate 2000 by penetrating the mask 1000 through the hollows 120, forming a graphic structure corresponding to the hollows 120 on the substrate 2000. The mask 1000 is configured to form a patterned structure on a target process object using the mask pattern formed by the first shield structure 110, that is, to form a patterned structure on the substrate 2000. As shown in FIG. 4, the process side T is the side of the mask 1000 close to the target process object, the first shield structure 110 is close to the process side T, and the second shield structure 210 is away from the process side T.

In some implementations, as shown in FIG. 4, the surface of the first shield structure 110 away from the process side T, i.e. the first surface F0, and the surface of the second shield structure 210 close to the process side T, i.e. the second surface F1, are coplanar with each other.

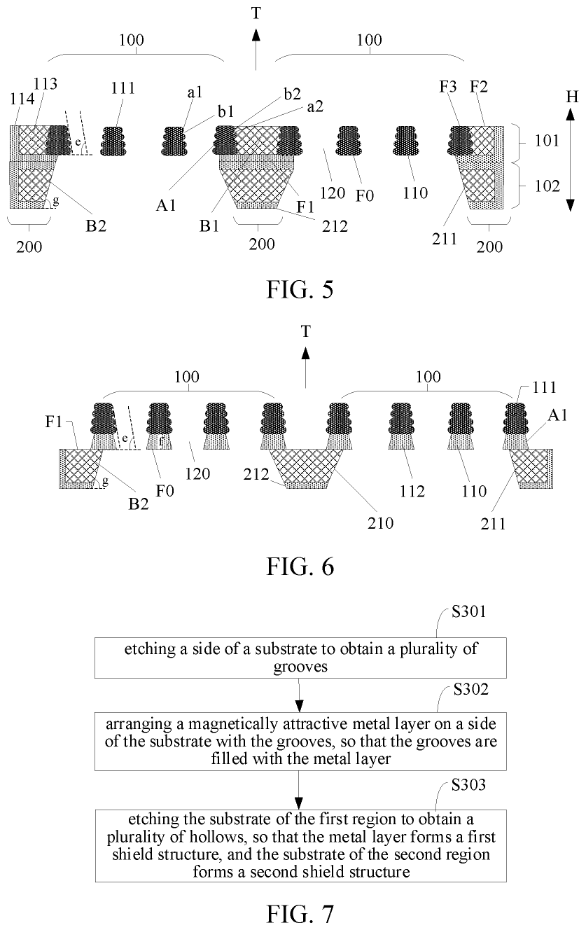

In some implementations, FIG. 5 is a schematic diagram of the cross-sectional structure of another mask provided by an embodiment of the present disclosure. As shown in FIG. 5, the first shield structure 110 may comprise a first substructure A1, and the second shield structure 210 may comprise a second substructure B1. The first substructure A1 is the first shield structure 110 closest to the boundary between the first region 100 and the second region 200, and the side surface of the second substructure B1 in the thickness direction H is connected with the side surface of the first substructure A1 in the thickness direction H. The side surface of the second substructure b1 in the thickness direction H may comprise: at least one second convex part a2 and at least one second concave part b2, the shape of the second convex part a2 is matched with the shape of the first concave part b1, the shape of the second concave part b2 is matched with the shape of the first convex part a1, and the curvature of the second concave part b2 is smaller than that of the second convex part a2.

Exemplarily, in the preparation process, the silicon-containing material layer of the second region 200 may be retained during etching the exposed metal layer of the silicon-containing material layer, to obtain the second substructure B1, so that the retention of the second substructure B1 can enhance the supporting force of the second shield structure 210, and the second substructure B1 can contribute to the stability of the first substructure A1. It may be understood that the first substructure A1 and the second substructure B1 may be embedded with each other.

In some implementations, as shown in FIG. 5, the thickness of the first substructure A1 is the same as that of the second substructure B1. The surface of the first shield structure 110 on a side away from the process side T is coplanar with the surface of the second substructure B1 on a side away from the process side T, that is, the first surface F0 is coplanar with the second surface F1.

In some implementations, as shown in FIG. 5, the surface of the first shield structure 110 on a side close to the process side T is coplanar with the surface of the second substructure B1 on a side close to the process side T. The surface of the first shield structure 110 on a side close to the process side T may be a fourth surface F3. Since the thickness of the first substructure A1 is the same as that of the second substructure B1, the surface of the second substructure B1 on a side close to the process side T is a third surface F2, that is, the third surface F2 is coplanar with the fourth surface F3.

In some implementations, as shown in FIG. 5, the first shield structure 110 may comprise a first substructure A1, and the second shield structure 210 may comprise a third substructure B2. The first substructure A1 and the third substructure B2 are stacked in the thickness direction H; the third substructure B2 is arranged on a side of the first substructure A1 and the second substructure B1 away from the process side T. The surface of the third substructure B2 on a side close to the process side T is coplanar with the surface of the second substructure B1 away from the process side T. The surface of the first shield structure 110 on a side close to the third substructure B2 is coplanar with the surface of the third substructure B2 on a side close to the first substructure A1.

In some implementations, as shown in FIG. 5, the side surface of the first shield structure 110 has a first slope angle “e”, which is an included angle between the plane formed by all of the raised vertices of the first convex parts a1 and the contact interface of the first substructure A1 and the third substructure B2. The contact interface of the first substructure A1 and the third substructure B2 is illustrated as a dashed line, and the plane formed by all of the raised vertices of the first convex parts al is illustrated as a dashed line. The side surface of the third substructure B2 in the thickness direction H has a second slope angle “g”, which is an included angle between the side surface of the third substructure B2 in the thickness direction H and the contact interface of the first substructure A1 and the third substructure B2. Both the first slope angle “e” and the second slope angle “g” may be acute angles. For example, the first slope angle “e” is greater than the second slope angle “g”. Exemplarily, the first slope angle “e” is formed by etching a silicon-containing material layer at the position of a groove and the process of etching the grooves may be a dry etching process. The second slope angle “g” may be a window for etching the exposed position of the second shield structure 210 to the hollow area, that is, liquid medicine etching can be used in etching the first region 100 of the second shield structure 210, such as wet etching with KOH liquid medicine. Because the etching processes for forming the first slope angle “e” and the second slope angle “g” are different, the angles are different. Thus, since the first slope angle “e” can affect the evaporation diffraction of the hollows 120 and the second slope angle “g” mainly affects the evaporation diffraction of the edges of a mask, setting the first slope angle “e” larger than the second slope angle “g” can ensure that the evaporation diffraction of each hollow is small and the requirement for the evaporation diffraction precision of the edges of a mask is not high. Therefore, the second slope angle “g” can be relatively small and the situation of larger diffraction has little influence on the overall evaporation process.

In some implementations, the metal layer in the first shield structure 110 may comprise a magnetically attractive metal material. The magnetically attractive metal material of the mask can be adsorbed by magnetic attraction, so that the mask can be attached to the target process object under the action of magnetic attraction on the basis of improving the resolution of the mask, can resist the gravity droop effect, and improve the precision of preparing a graphic structure.

In some implementations the first shield structure 110 may also comprise a silicon-containing material layer, which may comprise at least one of a monocrystalline silicon wafer and a silicon compound layer. A silicon-containing material layer may be arranged in the first shield structure 110, so that the stress of the first shield structure 110 can be increased and the hardness of the first shield structure 110 can be strengthened.

In some implementations, the second shield structure may comprise a magnetically attractive metal material, and arranging a magnetically attractive metal layer in the second shield structure 210 may enlarge the magnetically attractive area of a mask and better resist the gravity droop effect by the action of magnetic attraction.

In some implementations, in a case where the first shield structure 110 comprises a magnetically attractive metal layer and a first silicon-containing material layer, the magnetically attractive metal layer is close to the process side T, and the first silicon-containing material layer is away from the process side T with respect to the magnetically attractive metal layer.

In some implementations, as shown in FIG. 5, the second substructure B1 may comprise a first monocrystalline silicon wafer 113, and the third substructure B2 may comprise a first silicon compound layer 114, a second monocrystalline silicon wafer 211, and a second silicon compound layer 212. The first monocrystalline silicon wafer 113 and the first silicon compound layer 114 belong to the same substrate, and the second monocrystalline silicon wafer 211 and the second silicon compound layer 212 belong to the same substrate. The first silicon compound layer 114 is connected with the second silicon compound layer 212 in a bonding manner. The first monocrystalline silicon wafer 113 is located on a side of the first silicon compound layer 114 away from the second silicon compound layer 212, and the second monocrystalline silicon wafer 211 is located on a side of the second silicon compound layer 212 away from the first silicon compound layer 114.

In some implementations, as shown in FIG. 5, the first shield structure 110 may comprise a magnetically attractive metal layer 111. In the preparation process of a mask, the first shield structure 110 belongs to the first substrate 101, the second substructure B1 of the second shield structure 210 belongs to the first substrate 101, and the third substructure B2 belongs to the second substrate 102. The side of the first substrate 101 away from the magnetically attractive metal layer 111 is connected in a bonding manner with the side of the second substrate 102 close to the magnetically attractive metal layer 111.

In some implementations, as shown in FIG. 5, the thickness of the first shield structure 110 is smaller than that of the second shield structure 210. Therefore, since the second shield structure 210 serves as a support frame and the first shield structure 110 is configured to form a mask pattern, a relatively thick thickness of the second shield structure 210 can improve the supporting force and stability of the mask, and a relatively thin thickness of the first shield structure 110 can improve the pattern resolution of the mask.

In some implementations, as shown in FIG. 5, the thickness of the first monocrystalline silicon wafer 113 is less than or equal to 20 μm. The thickness of the second monocrystalline silicon wafer 211 is greater than or equal to 100 μm. Exemplarily, the sum of the thicknesses of the first monocrystalline silicon wafer 113 and the first silicon compound layer 114 is smaller than the thickness of the second shield structure 210, that is, the thickness of the substrate arranged with the magnetically attractive metal layer 111 is smaller than the thickness of the second shield structure 210.

In some implementations, FIG. 6 is a schematic diagram of the cross-sectional structure of yet another mask provided by an embodiment of the present disclosure. As shown in FIG. 6, the first shield structure 110 may comprise: a magnetically attractive metal layer 111 close to the process side T, and a first silicon-containing material layer 112 away from the process side T. The first silicon-containing material layer 112 may comprise one or two of a monocrystalline silicon wafer, silicon oxide, and silicon nitride, and the first silicon-containing material layer 112 may serve to increase the stress of the first shield structure 110.

In some implementations, as shown in FIG. 6, the surface of the first shield structure 110 on a side away from the process side T (i.e. the first surface F0) and the surface of the third substructure B2 on a side close to the process side T (i.e. the second surface F1) are coplanar with each other, that is, the first surface F0 is coplanar with the second surface F1.

In some implementations, as shown in FIG. 6, the first shield structure 110 and the second shield structure 210 may belong to different substrates, and the first shield structure 110 and the second shield structure 210 belonging to different substrates may be connected in a bonding manner. A surface of the first shield structure 110 on a side away from the process side T (i.e. the first surface F0) and a surface of the second shield structure 210 on a side close to the process side T (the second surface F1) may be connected in a bonding manner, i.e. the first surface F0 and the second surface F1 may be connected together in a bonding manner.

In some implementations, as shown in FIG. 6, the second shield structure 210 may comprise a second monocrystalline silicon wafer 211 and a second silicon compound layer 212. The second silicon compound layer 212 may comprise one or both of silicon oxide and silicon nitride. The second silicon compound layer 212 may serve to protect the first monocrystalline silicon wafer 113 in an etching process. The second monocrystalline silicon wafer 211 and the second silicon compound layer 212 form a second silicon-containing material layer.

Exemplarily, as shown in FIG. 6, the first shield structure 110 and the second shield structure 210 may belong to the same substrate, which is not limited in the embodiments of the present disclosure.

In some implementations, as shown in FIG. 6, the first slope angle corresponding to the first silicon-containing material layer 112 may be denoted as “f”, and the first slope angle corresponding to the magnetically attractive metal layer 111 may be denoted as “e”. The difference between the first slope angle “e” corresponding to the magnetically attractive metal layer 111 and the first slope angle “f” corresponding to the first silicon-containing material layer 112 is less than or equal to 5°. Exemplarily, the side surface of the first silicon-containing material layer 112 may not have a concave-convex structure, in which case the first slope angle “f” of the first silicon-containing material layer 112 may be an included angle between the side surface of the first silicon-containing material layer 112 and the interface of the first shield structure 110 and the third substructure B2. Exemplarily, the first slope angle “e” may be an included angle between the plane formed by all of the raised vertices on the side surface of the magnetically attractive metal layer 111 and the contact interface of the first substructure A1 and the third substructure B2. In FIG. 6, the contact interface of the first substructure A1 and the third substructure B2 is illustrated as a dashed line. The plane formed by all of the raised vertices on the side surface of the magnetically attractive metal layer 111 is illustrated as a dashed line. In practical application, since the first slope angle “e” corresponding to the magnetically attractive metal layer 111 is determined by the inner walls of the grooves filled by the magnetically attractive metal layer 111, and the first slope angle “f” corresponding to the first silicon-containing material layer 112 is obtained by etching the silicon-containing material layer between the magnetically attractive metal layers 111, a dry etching process may be used in both processes. However, since the formation of a groove can be obtained through multiple etchings, the first slope angle “e” corresponding to the magnetically attractive metal layer 111 and the first slope angle “f” corresponding to the first silicon-containing material layer 112 will be different, but the difference will not exceed 5°.

Exemplarily, as shown in FIG. 6, a surface of the first substructure A1 on a side close to the third substructure B2 (i.e., the first surface F0) and a surface of the third substructure B2 on a side close to the first substructure A1 (i.e., the second surface F1) may be connected in a bonding manner. That is, it can be understood that, in FIG. 6, since the first silicon-containing material layer 112 and the second shield structure 210 belong to different substrates, the first surface F0 and the second surface F1 in contact with each other may be connected in a bonding manner.

In some implementations, as shown in FIG. 5 and FIG. 6, the side surface of the second silicon compound layer 212 in the thickness direction H is parallel to the side surface of the second monocrystalline silicon wafer 211 in the thickness direction H. In the preparation process, since the second silicon compound layer 212 and the first monocrystalline silicon wafer 113 may be etched in the same way, the etching process may be the same or may be etched separately, and the etched interfaces may be parallel.

In some implementations, as shown in FIG. 5 and FIG. 6, the thickness of the magnetically attractive metal layer 111 is less than the inner diameter of the hollows 120. Exemplarily, the thickness of the magnetically attractive metal layer 111 is less than or equal to 10 um. Normally, the line width of the patterned structures of the target process object corresponding to the hollows 120 and the resolution of the hollows may determine the resolution of the patterned structures. In the groove etching process, the inner diameter of the hollows 120 may be the spacing between the grooves, and therefore, the size of the hollows 120 is affected by the etching precision. The inner diameter of the hollows 120 that can be obtained is several microns, and therefore, the thickness of the magnetically attractive metal layer 111 is about several microns.

In some implementations, as shown in FIG. 6, the first silicon-containing material layer 112 and the second shield structure 210 may belong to different substrates.

In a mask provided by an embodiment of the present disclosure, a magnetically attractive metal layer with several microns is embedded on the silicon-based mask, and micropores on the magnetically attractive metal layer replace the micropore structure of the silicon-based mask. Therefore, the mask in use can be adsorbed by a magnetic field, and different stress film layers can be arranged above and under the electroformed metal to improve the structural strength, thus forming an ultra-thin metal mask with a composite structure. The process of this mask can avoid the fragmentation problem that appears easily in the micropore etching process on the silicon substrate, and meanwhile, the electroformed metal has magnetism, which can be tightly attached to the evaporation substrate through magnets. The process of a mask provided by an embodiment of the present disclosure can adopt the existing relatively mature semiconductor processes, and thus the process has relatively high universality.

An exemplary embodiment of the present disclosure further provides a preparation method of a mask. FIG. 7 is an exemplary flow diagram of a preparation method of a mask provided by an embodiment of the present disclosure. As shown in FIG. 7, the preparation method of the mask may comprise:

S301: etching a side of a substrate to obtain a plurality of grooves, wherein the substrate may comprise a first region and a second region, the second region surrounds the first region, and the substrate may comprise a silicon-containing material layer, wherein sidewalls of the grooves in a depth direction may comprise at least one third concave part and at least one third convex part, and the third concave part is connected with the third convex part.

Exemplarily, as shown in FIGS. 1-3, the second region 200 surrounds the first region 100.

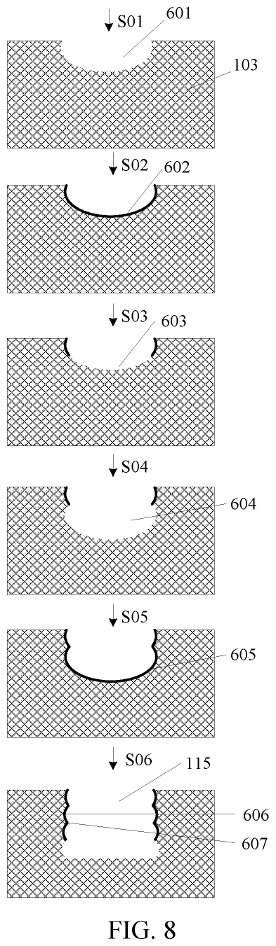

In some implementations, FIG. 8 is an exemplary flow diagram of an etching process of a groove provided by an embodiment of the present disclosure. As shown in FIG. 8, Step S301 may comprise the following Steps S01 to S06:

S01: performing a first etching on a side of the substrate 103 to obtain a plurality of first grooves 601.

Here, the etching process of only one groove is schematically illustrated in FIG. 8 and a plurality of grooves may be etched on the substrate 103. For example, a dry etching process may be used in the isotropic etching performed on the substrate 103 to obtain a plurality of first grooves 601.

S02: performing a first passivation treatment on the inner walls of the first grooves 601.

Exemplarily, as shown in FIG. 8, the first passivation treatment may form a first passivation layer 602 on the inner wall of the first groove 601.

Then, before performing a second etching, Step S301 may further comprise:

S03: performing a plasma bombardment on the first passivation layer 602 to remove the passivation layer at the bottom of the first passivation layer 602, which can form a window 603 on the first passivation layer 602 to facilitate the second etching.

Exemplarily, sequentially performing a second etching treatment and a second passivation treatment of all the first grooves having been performed the first passivation treatment, until a plurality of grooves with given depths are obtained, wherein the sidewalls of the grooves in the depth direction may comprise at least one third concave part and at least one third convex part, and the inner diameter of the grooves corresponding to the position of the third concave part is larger than the inner diameter of the grooves corresponding to the position of the third convex part.

In some implementations, the sequentially performing a second etching treatment and a second passivation treatment of all the first grooves having been performed the first passivation treatment, until a plurality of grooves with given depths are obtained, may comprise:

S04: performing a second etching on the first groove 601 which can be etched through the window 603 to obtain a second groove 604.

S05: performing a second passivation treatment on the inner wall of the second groove 604 to obtain a second passivation layer 605.

S06: repeating the above steps of S03, S04, and S05. Finally, the etching can be stopped when the depth of the groove 115 reaches a given depth according to the requirement on actual groove depth.

Exemplarily, as shown in FIG. 8, the sidewall of the groove 115 in the depth direction may comprise a third concave part 606 and a third convex part 607. The number of the third concave part 606 is 4 and the number of the third convex part 607 is 3, which are only schematic and are not specifically limited by the present disclosure.

S302: arranging a metal layer on a side of the substrate with the grooves so that the grooves are filled with the metal layer.

Exemplarily, the metal layer may be configured to form a shield structure of a mask and the arrangement of the grooves is configured to form an embedding position and size of the metal layer.

S303: etching the substrate of the first region to obtain a plurality of hollows, so that the metal layer forms a first shield structure, and the substrate of the second region forms a second shield structure, wherein, an orthographic projection of the first shield structure in the first region surrounds an orthographic projection of the hollows in the first region, the first shield structure is configured to form a mask pattern, a side surface of the first shield structure in a thickness direction may comprise at least one first convex part and at least one first concave part, the first convex part is connected with the first concave part, the first convex part has the same shape with the third concave part, and the first concave part has the same shape with the third convex part.

Exemplarily, as shown in FIG. 5 and FIG. 6, the first convex part a1 may have the same shape with the third concave part 606, and the first concave part b1 may have the same shape with the third convex part 607.

Exemplarily, etching the substrate material outside the metal layer of the first region 100 may obtain a plurality of hollows 120, so that the shape of the metal layer may form a first shield structure 110, while the pattern formed by the first shield structure 110 is a mask pattern, and the pattern of the hollows 120 may be a pattern required by the evaporated organic light-emitting layer. The second shield structure 210 may be configured as serving as a frame supporting the entire mask and the second shield structure 210 may be configured as a fixed support or clamp during the process.

In the preparation method of a mask provided by an embodiment of the present disclosure, a metal layer is arranged in the first shield structure 110, and a silicon-containing material layer is arranged in the second shield structure 210, so that the micropore structure of the mask is made of metal material, and the second shield structure for supporting is made of silicon material. The process of the silicon mask can be combined with the electroforming process, that is, grooves can be arranged on the silicon-containing material layer first, and a concave-convex sidewall can be formed during the groove arranging. The metal material is filled into the grooves, and then the silicon-containing material layer between the grooves is removed, so that the first shield structure 110 formed by the metal layer can be obtained. The side surface of the first shield structure 110 will form the first convex part a1 and the first concave part b1. The thickness of the silicon-containing material layer etched can be controlled to be thinner, and the precision of etching the thinner silicon-containing material layer is higher than that of etching the thicker metal, so that the density of hollows on the obtained first shield structure is higher, and the resolution of the obtained mask pattern is higher. In addition, the metal layer combined with the mask can be adsorbed by magnetic attraction, so that the mask can be attached to the target process object under the action of magnetic attraction on the basis of improving the resolution of the mask, and can resist the gravity droop effect. In addition, the first shield structure 110 is the bulk micropore structure of the mask, the area of the mask occupied by the first shield structure 110 is larger than that occupied by the second shield structure 210, and then, the area of the mask occupied by the metal layer is larger than that occupied by the second shield structure 210. In the manufacturing process of a mask, compared with supporting or clamping the second shield structure 210, the fixing uniformity and fixing strength of the metal layer under the action of magnetic attraction are stronger, which can ensure the uniformity of the attaching distance between the mask and the target process object and have better resistance to the gravity droop effect.

In some implementations, the substrate may comprise a monocrystalline silicon wafer, and thus, the prepared mask can be suitable for the preparation of wafer-level display panels. Alternatively, the substrate may also comprise glass, and thus, a mask with a larger size can be made and can be suitable for the production of large-size display panels.

In some implementations, the preparation method of a mask provided by an embodiment of the present disclosure may be implemented using a single substrate.

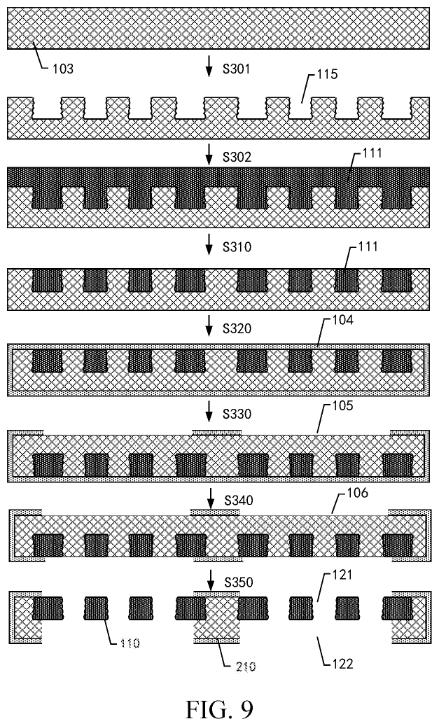

Exemplarily, FIG. 9 is an exemplary first process flow diagram of a preparation method of a mask provided by an embodiment of the present disclosure. As shown in FIG. 9, the preparation method of the mask may comprise the following steps:

In step S301, the substrate 103 is etched to obtain grooves 115. For example, the substrate 103 may be a monocrystalline silicon wafer.

In step S302, a metal layer is arranged. For example, the metal layer may be a magnetically attractive metal layer 111.

In some implementations, step S302 may comprise: arranging a seed layer; a magnetically attractive metal layer 111 is electroplated on the seed layer.

Exemplarily, the seed layer may serve to improve the adhesion of the substrate material to the magnetically attractive metal layer. The seed layer and the magnetically attractive metal layer may have the same material, or may have different materials. The seed layer may be arranged by atomic layer deposition, such as magnetron sputtering or the like. Exemplarily, the seed layer may comprise a highly conductive material such as copper, gold, silver, or aluminum or the like.

Exemplarily, since the thickness of the film layer prepared by a film forming method of magnetron sputtering is relatively thin, and the thickness of the magnetically attractive metal layer 111 is difficult to be prepared by the magnetron sputtering method, the magnetically attractive metal layer 111 can be prepared by electroplating. At that time, the seed layer serves to enhance the adhesion force of the magnetically attractive metal layer 111.

Exemplarily, the magnetically attractive metal layer 111 may be configured to form a shield structure of a mask and the grooves 115 may be configured to form an embedding position and size of the magnetically attractive metal layer 111.

Before step S303, the preparation method of a mask may further comprise:

S310: chemically mechanical grinding the substrate on a side arranged with the magnetically attractive metal layer 111 to remove the magnetically attractive metal layer 111 between openings of the adjacent grooves, and controlling the thickness of the magnetically attractive metal layer 111 in the grooves to reach a given thickness.

Exemplarily, step S310 removes the excess magnetically attractive metal layer 111 by chemically mechanical grinding, that is, removes a whole layer on the surface of the magnetically attractive metal layer 111, grinds away the magnetically attractive metal layer 111 attached to the surface between the openings of the grooves 115, and grinds away the excess magnetically attractive metal material in the grooves and a portion of the substrate according to a given thickness of the magnetically attractive metal layer 111 required.

S320: arranging a silicon compound layer 104 on a surface of the substrate.

Exemplarily, the silicon compound layer 104 may serve to protect the monocrystalline silicon wafer during etching, and may enhance the overall stress of the substrate, strengthen hardness, and avoid easy deformation due to hardness loss caused by etching.

S330: etching the silicon compound layer 104 on a side away from the magnetically attractive metal layer to obtain at least one first opening 105, wherein an orthographic projection of the first opening 105 on the substrate covers the first region.

Exemplarily, the substrate may be turned over 180° before the etching in step S330, and the first opening 105 is configured to expose the monocrystalline silicon wafer of the first region.

S303: etching the substrate of the first region to obtain a plurality of hollows, so that the metal layer forms a first shield structure, and the substrate of the second region forms a second shield structure, wherein, an orthographic projection of the first shield structure in the first region surrounds an orthographic projection of the hollows in the first region, the first shield structure is configured to form a mask pattern, a side surface of the first shield structure in a thickness direction may comprise at least one first convex part and at least one first concave part, the first convex part is connected with the first concave part, the first convex part has the same shape with the third concave part, and the first concave part has the same shape with the third convex part.

In some implementations, as shown in FIG. 9, step S303 may comprise the following steps S340 to S350:

S340: etching the silicon compound layer 104 on a side close to the magnetically attractive metal layer to obtain at least one second opening 106, wherein an orthographic projection of the second opening 106 on the substrate covers the first region.

Exemplarily, the substrate may be turned over 180° before the etching in step S340, and the second opening 106 is configured to expose the monocrystalline silicon wafer of the first region. For example, a dry etching process may be used in the etching of the silicon compound layer 104. For example, the etching of the silicon compound layer 104 may be accomplished by exposure and development of a photoresist, which will not be further described here.

S350: through the first opening 105 and the second opening 106, etching the substrate of the first region to obtain a plurality of hollows, so that the magnetically attractive metal layer forms a first shield structure, and the substrate of the second region forms a second shield structure.

Exemplarily, as shown in FIG. 9, the substrate can be immersed in a potassium hydroxide (KOH) etching solution for etching in step S350. The KOH etching solution does not etch the silicon compound layer and the magnetically attractive metal layer, and the monocrystalline silicon wafer exposed by the first opening 105 and the second opening 106 can be etched away to obtain the first hollows 121 and the second hollows 122 respectively, so that the first hollows 121 are communicated with the second hollows 122 to obtain the hollows 120, the magnetically attractive metal layer forms the first shield structure 110, and the substrate of the second region and the retained silicon compound form the second shield structure 210.

A single substrate is used in the preparation method of a mask provided by an embodiment of the present disclosure, which can simplify the process flow and has low cost.

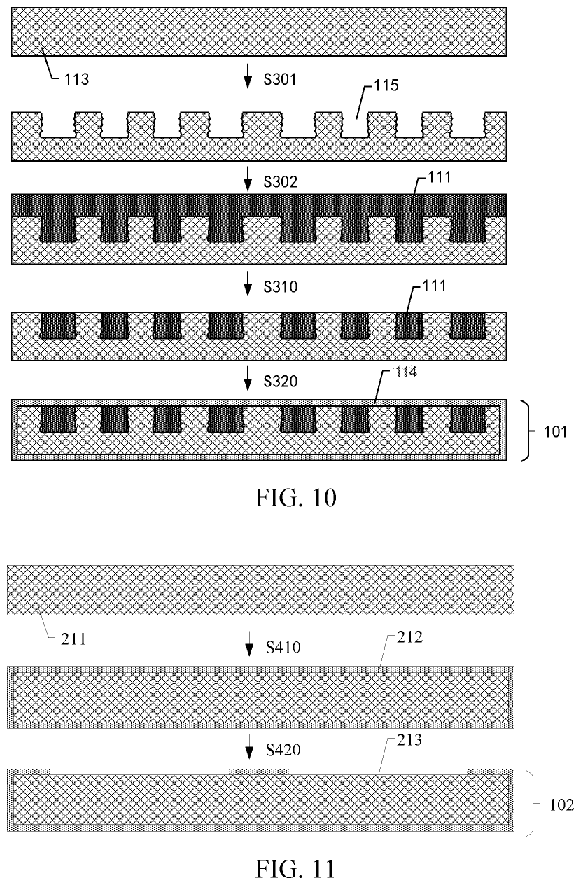

In some implementations, FIG. 10 is an exemplary second process flow diagram of a preparation method of a mask provided by an embodiment of the present disclosure. As shown in FIG. 10, the preparation method of the mask may comprise:

Step S301 may comprise: etching a side of the first monocrystalline silicon wafer 113 of the first substrate 101 to obtain a plurality of grooves 115.

Step S302 may comprise: arranging the magnetically attractive metal layer 111 on a side of the first substrate 101 with the grooves 115, so that the plurality of grooves 115 are filled with the magnetically attractive metal layer 111.

Exemplarily, the magnetically attractive metal layer 111 may be configured to form a shield structure of a mask and the grooves 115 may be configured to form an embedding position and size of the magnetically attractive metal layer 111.

Step S310 may comprise: chemically mechanical grinding the first substrate 101 on a side arranged with the magnetically attractive metal layer 111 to remove the magnetically attractive metal layer 111 between openings of the adjacent grooves 115, and controlling the thickness of the magnetically attractive metal layer 111 in the grooves 115 to reach a given thickness.

Step S320 may comprise: arranging a first silicon compound layer 114 on the surface of the first monocrystalline silicon wafer 113.

Exemplarily, the first silicon compound layer 114 may serve to protect the monocrystalline silicon wafer 113 during etching, and may enhance the overall stress of the substrate, strengthen hardness, and avoid easy deformation due to hardness loss caused by etching.

FIG. 11 is an exemplary third process flow diagram of a preparation method of a mask provided by an embodiment of the present disclosure. As shown in FIG. 11, before step S303, the preparation method of a mask may further comprise:

S410: arranging a second silicon compound layer 212 on an outer surface of the second monocrystalline silicon wafer 211 of the second substrate 102.

S420: etching the second silicon compound layer 212 on a side of the second substrate 102 to obtain at least one third opening 213, wherein an orthographic projection of the third opening 213 on the second substrate 102 covers the first region 110.

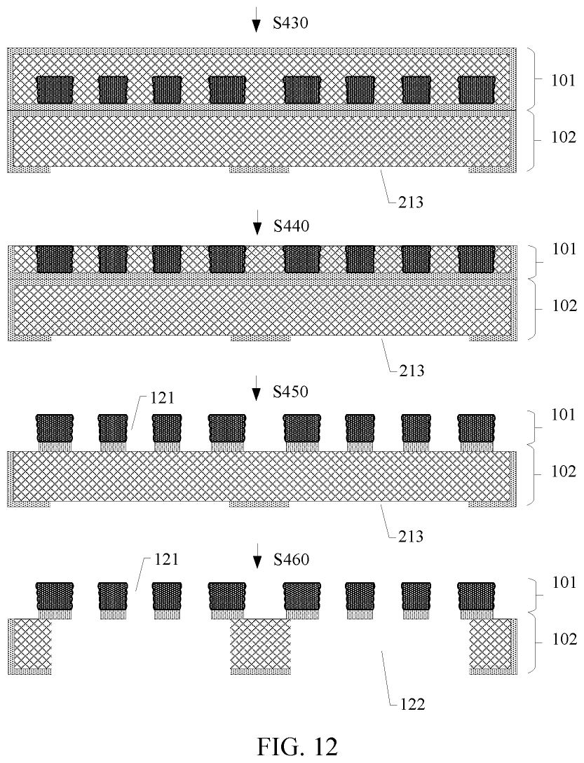

FIG. 12 is an exemplary fourth process flow diagram of a preparation method of a mask provided by an embodiment of the present disclosure. As shown in FIG. 12, before step S303, the preparation method of a mask may further comprise:

S430: connecting a surface of the first substrate 101 on a side arranged with the magnetically attractive metal layer 111 in a bonding manner with a surface of the second substrate 102 on a side away from the third opening 213, to obtain a third substrate.

Exemplarily, marks on the substrate may be used for aligning in the bonding process.

S303: etching the substrate of the first region to obtain a plurality of hollows, so that the metal layer forms a first shield structure, and the substrate of the second region forms a second shield structure, wherein, an orthographic projection of the first shield structure in the first region surrounds an orthographic projection of the hollows in the first region, the first shield structure is configured to form a mask pattern, a side surface of the first shield structure in a thickness direction may comprise at least one first convex part and at least one first concave part, the first convex part is connected with the first concave part, the first convex part has the same shape with the third concave part, and the first concave part has the same shape with the third convex part.

In some implementations, as shown in FIG. 12, step S303 may comprise the following steps S440 to S460:

S440: chemically mechanical grinding the third substrate on a side arranged with the magnetically attractive metal layer to remove the magnetically attractive metal layer between openings of the adjacent grooves, and controlling the thickness of the magnetically attractive metal layer in the grooves to reach a given thickness.

S450: etching the first substrate outside the magnetically attractive metal layer of the first region to obtain a plurality of first hollows 121, wherein the magnetically attractive metal layer surrounds the first hollows 121.

Exemplarily, the etching in step S450 may protect the magnetically attractive metal layer with a photoresist, and may etch the first monocrystalline silicon wafer and the first silicon compound. The dry etching gases for etching the monocrystalline silicon wafer and the silicon compound are different, and therefore, switching of the etching gases is required in the etching process of the two layers. A photoresist can protect the magnetically attractive metal layer from being damaged, and can also use the magnetically attractive metal layer as a mask for etching. Because dry etching gases have no etching function for the magnetically attractive metal layer, the magnetically attractive metal layer can be used instead of a photoresist.

S460: etching the second monocrystalline silicon wafer of the second substrate of the first region through the third opening 213 to obtain at least one second hollow 122, wherein the second hollows 122 are communicated with the first hollows 121, and the second hollows 122 are in one-to-one correspondence with the third openings 213. Therefore, the communication of the second hollows 122 with the first hollows 121 may form hollows in the first region, the magnetically attractive metal layer may form a first shield structure in the first region, and the first monocrystalline silicon wafer, the first silicon compound layer, the second monocrystalline silicon wafer and the second silicon compound layer may form a second shield structure in the second region.

Exemplarily, a KOH etching solution may be used for etching in step S460, and a surface outside the third opening 213 may be coated with a protective material such as a photoresist or the like before etching.

Exemplarily, using the process flow shown in FIG. 10, FIG. 11 and FIG. 12 above, a mask structure as shown in FIG. 5 can be prepared.

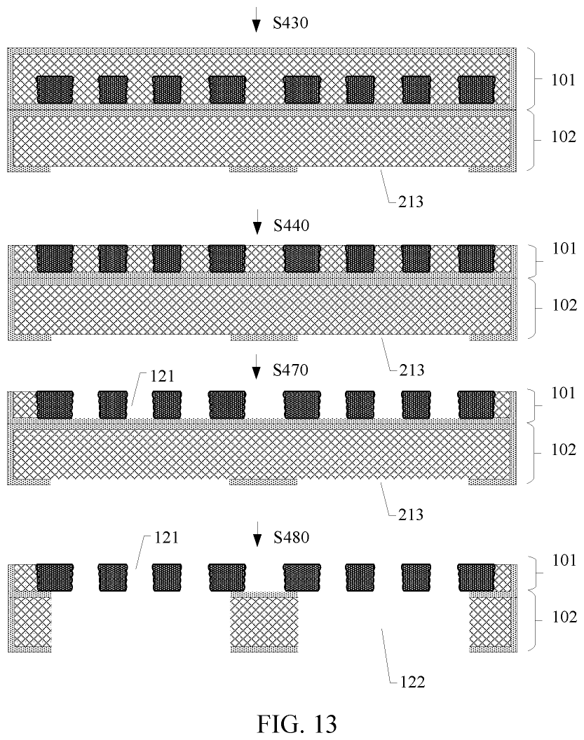

In some implementations, FIG. 13 is an exemplary fifth process flow diagram of a preparation method of a mask provided by an embodiment of the present disclosure.

As shown in FIG. 13, before step S303, the preparation method of a mask may further comprise:

S430: connecting a surface of the first substrate 101 on a side arranged with the magnetically attractive metal layer 111 in a bonding manner with a surface of the second substrate 102 on a side away from the third opening 213, to obtain a third substrate.

As shown in FIG. 13, step S303 may comprise:

S440: chemically mechanical grinding the third substrate on a side arranged with the magnetically attractive metal layer to remove the magnetically attractive metal layer between openings of the adjacent grooves, and controlling the thickness of the magnetically attractive metal layer in the grooves to reach a given thickness.

S470: etching the first monocrystalline silicon wafer outside the magnetically attractive metal layer of the first region to obtain a plurality of first hollows 121, wherein the magnetically attractive metal layer surrounds the first hollows 121.

Exemplarily, the etching in step S470 may be dry etching.

S480: etching the second monocrystalline silicon wafer of the second substrate of the first region through the third openings 213 and then etching the first silicon compound and the second silicon compound in the first region to obtain at least one second hollow 122, wherein the second hollows 122 are communicated with the first hollows 121, and the second hollows 122 are in one-to-one correspondence with the third openings 213. Therefore, the communication of the second hollows 122 with the first hollows 121 may form hollows in the first region, the magnetically attractive metal layer may form a first shield structure in the first region, and the first monocrystalline silicon wafer, the first silicon compound layer, the second monocrystalline silicon wafer and the second silicon compound layer may form a second shield structure in the second region.

Exemplarily, a KOH etching solution may be used in step S480 to perform etching of the second monocrystalline silicon wafer, and etching of the first silicon compound and the second silicon compound may use other liquid medicine etching. Switching of different liquid medicines is required in step S480.

Exemplarily, using the process flow shown in FIG. 10, FIG. 11 and FIG. 13 above, another exemplary mask structure can be prepared.

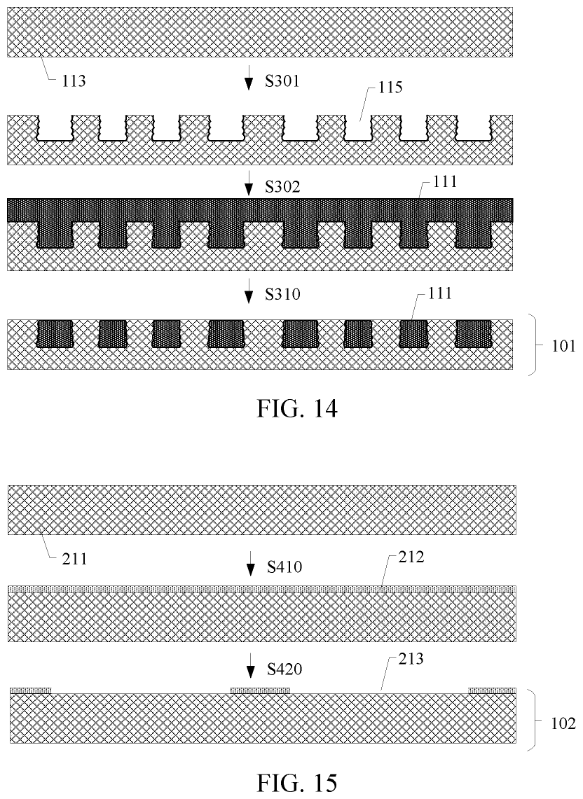

In some implementations, FIG. 14 is an exemplary sixth process flow diagram of a preparation method of a mask provided by an embodiment of the present disclosure. As shown in FIG. 14, the preparation method of the mask may comprise:

Step S301 may comprise: etching a side of the first monocrystalline silicon wafer 113 of the first substrate 101 to obtain a plurality of grooves 115.

Step S302 may comprise: arranging the magnetically attractive metal layer 111 on a side of the first substrate 101 with the grooves 115, so that the plurality of grooves 115 are filled with the magnetically attractive metal layer 111.

Step S310 may comprise: chemically mechanical grinding the first substrate 101 on a side arranged with the magnetically attractive metal layer 111 to remove the magnetically attractive metal layer 111 between openings of the adjacent grooves 115, and controlling the thickness of the magnetically attractive metal layer 111 in the grooves 115 to reach a given thickness.

Here, as shown in FIG. 14, the first substrate 101 is not arranged with a first silicon compound layer.

In some implementations, FIG. 15 is an exemplary seventh process flow diagram of a preparation method of a mask provided by an embodiment of the present disclosure. As shown in FIG. 15, the preparation method of the mask may comprise:

Step S410 may be: arranging a second silicon compound layer 212 on a side surface of the second monocrystalline silicon wafer 211 of the second substrate.

Step S420 may be: etching the second silicon compound layer 212 on a single side thereof to obtain the third opening 213.

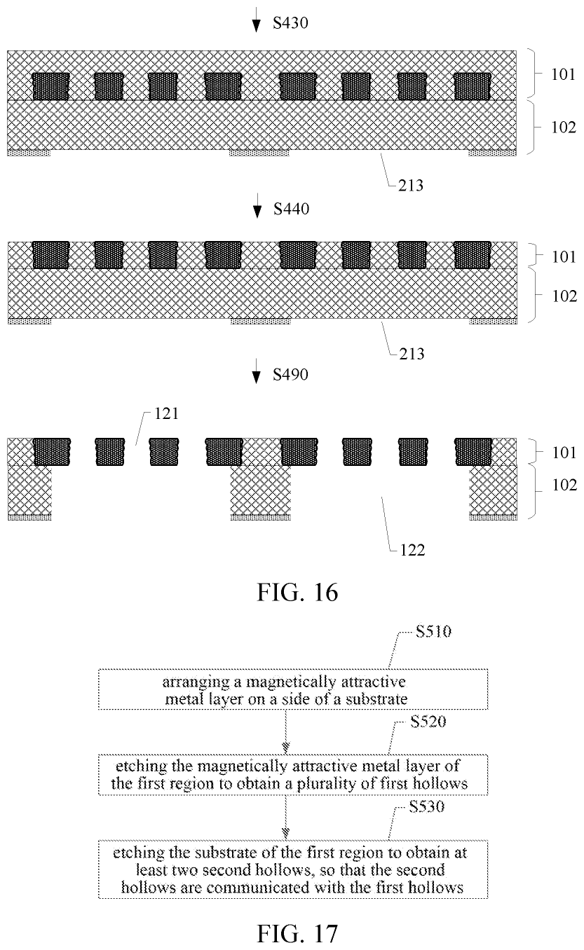

In some implementations, FIG. 16 is an exemplary eighth process flow diagram of a preparation method of a mask provided by an embodiment of the present disclosure.

As shown in FIG. 16, before step S303, the preparation method of a mask may further comprise:

S430: connecting a surface of the first substrate 101 on a side arranged with the magnetically attractive metal layer 111 in a bonding manner with a surface of the second substrate 102 on a side away from the third opening 213, to obtain a third substrate.

As shown in FIG. 16, step S303 may comprise:

S440: chemically mechanical grinding the third substrate on a side arranged with the magnetically attractive metal layer to remove the magnetically attractive metal layer between openings of the adjacent grooves, and controlling the thickness of the magnetically attractive metal layer in the grooves to reach a given thickness.

S490: through the third opening 213, the first monocrystalline silicon wafer and the second monocrystalline silicon wafer in the first region are etched with a KOH etching solution to obtain the first hollows 121 and the second hollows 122, respectively, so that the first hollows 121 and the second hollows 122 are communicated. Wherein, the magnetically attractive metal layer surrounds the first hollows 121, the second hollow 122 are communicated with the first hollows 121, and the second hollows 122 are in one-to-one correspondence with the third openings 213. Therefore, the communication of the second hollows 122 with the first hollows 121 may form hollows in the first region, the magnetically attractive metal layer may form a first shield structure in the first region, and the first monocrystalline silicon wafer, the second monocrystalline silicon wafer and the second silicon compound layer may form a second shield structure in the second region.

Exemplarily, using the process flow shown in FIG. 14, FIG. 15 and FIG. 16 above, yet another exemplary mask structure can be prepared.

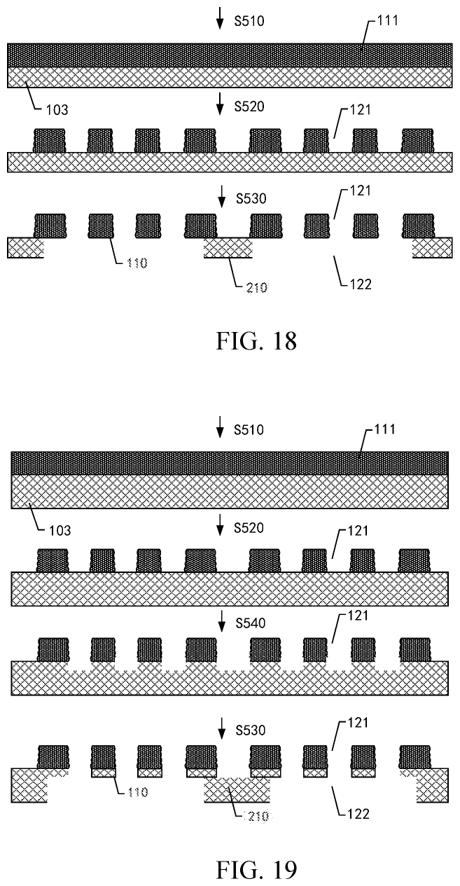

The embodiments of the present disclosure further provide a preparation method of a mask. FIG. 17 is an exemplary flow diagram of a preparation method of another mask provided by an embodiment of the present disclosure; and FIG. 18 is an exemplary ninth process flow diagram of a preparation method of a mask provided by an embodiment of the present disclosure. As shown in FIG. 17 and FIG. 18, the preparation method of the mask may comprise:

S510: arranging a magnetically attractive metal layer on a side of a substrate, wherein the substrate comprises a first region and a second region, the second region surrounds the first region, and the substrate comprises a silicon-containing material layer.

Exemplarily, before the film forming of the magnetically attractive metal layer 111, a seed layer may also be sputtered firstly on the substrate 103, and then the magnetically attractive metal layer 111 is electroplated on the seed layer.

S520: etching the magnetically attractive metal layer of the first region to obtain a plurality of first hollows, wherein the magnetically attractive metal layer between the first hollows forms a first shield structure, and the first shield structure is configured to form a mask pattern.

Exemplarily, if the seed layer is arranged, the formation of the first hollows also requires etching of the seed layer, and wet etching may be used. The first hollows 121 penetrate through the magnetically attractive metal layer 111.

S530: etching the substrate of the first region to obtain at least two second hollows, so that the second hollows are communicated with the first hollows, wherein the substrate of the second region forms a second shield structure.

As shown in FIG. 18, the etching of the substrate 103 may be dry etching and may be performed from a side away from the magnetically attractive metal layer 111, to obtain the second hollows 122.

Exemplarily, FIG. 19 is an exemplary tenth process flow diagram of a preparation method of a mask provided by an embodiment of the present disclosure. As shown in FIG. 19, after step S520, the preparation method of a mask may comprise:

step S540: etching the substrate on a side where the magnetically attractive metal layer 111 is located using the magnetically attractive metal layer 111 as a mask, and the first hollows 121 penetrate through the magnetically attractive metal layer and part of the substrate. Wherein, the magnetically attractive metal layer surrounds the first hollows 121.

step S530: etching the other side of the substrate to obtain the second hollows 122 in the first region, and the second hollows 122 are communicated with the first hollows 121.

Exemplarily, a silicon compound layer may also be arranged in the process flow of a mask shown in FIG. 18 and FIG. 19 to enhance the hardness of the substrate and protect the substrate, which is not illustrated in detail herein.

Exemplarily, in the above-described embodiments, the description of each embodiment has its own emphasis and parts of an embodiment that are not described in detail can be referred to related descriptions of other embodiments.

The above embodiments are only used to illustrate the technical schemes of the present disclosure, rather than limiting the technical schemes. Although the present disclosure is described in detail with reference to the foregoing embodiments, those of ordinary skills in the art should understand that they may still make modifications to the technical schemes described in the embodiments, or make equivalent replacements to some technical features in the technical schemes thereof, without departing from scope of the technical schemes of the embodiments of the present disclosure.

Although preferred embodiments of the present specification have been described, those skilled in the art may make additional changes and modifications to these embodiments once basic inventive concepts are known. Therefore, the appended claims are intended to be interpreted to encompass preferred embodiments as well as all changes and modifications falling within the scope of the present specification.

Apparently, those skilled in the art may make various modifications and variations to the present specification without departing from the spirit and scope of the present specification. Thus, if these modifications and variations to the present specification are within the scope of the claims of the present specification and their equivalent techniques, the present specification may be intended to include these modifications and variations.

1. A mask, comprising:
a first region comprising a first shield structure and a plurality of hollows, an orthographic projection of the first shield structure in the first region surrounding an orthographic projection of the hollows in the first region, and the first shield structure being configured to form a mask pattern; and
a second region surrounding the first region, the second region comprising a second shield structure;
wherein, a side surface of the first shield structure in a thickness direction comprises at least one first convex part and at least one first concave part, and the first convex part is connected with the first concave part; and
the first shield structure comprises a metal layer, and the second shield structure comprises a silicon-containing material layer.

2. The mask according to claim 1, wherein,
in a direction perpendicular to the thickness direction of the first shield structure, in the first convex part and the first concave part adjacent to each other, the size of the first shield structure corresponding to the position of the first convex part is larger than the size of the first shield structure corresponding to the position of the first concave part; and
the curvature of the first convex part is smaller than the curvature of the first concave part.

3. The mask according to claim 2, wherein,
the first shield structure comprises a first substructure, the second shield structure comprises a second substructure, the first substructure is the first shield structure closest to a boundary between the first region and the second region, and a side surface of the second substructure in the thickness direction is connected with a side surface of the first substructure in the thickness direction; and
the side surface of the second substructure in the thickness direction comprises at least one second convex part and at least one second concave part, the shape of the second convex part is matched with the shape of the first concave part, the shape of the second concave part is matched with the shape of the first convex part, and the curvature of the second concave part is smaller than the curvature of the second convex part.

4. The mask according to claim 3, wherein,
the thickness of the first substructure is the same as that of the second substructure.

5. The mask according to claim 3, wherein, the mask is configured to form a patterned structure on a target process object using the mask pattern formed by the first shield structure, and a side of the mask close to the target process object is a process side;
the first shield structure satisfies at least one of the following conditions:
a surface of the first shield structure on a side away from the process side is coplanar with a surface of the second substructure on a side away from the process side;
and, a surface of the first shield structure on a side close to the process side is coplanar with a surface of the second substructure on a side close to the process side.

6. The mask according to claim 2, wherein,
the first shield structure comprises a first substructure, the second shield structure comprises a third substructure, the first substructure is the first shield structure closest to a boundary between the first region and the second region, and the first substructure and the third substructure are stacked in the thickness direction;
a side surface of the first shield structure has a first slope angle, the first slope angle is an included angle between the plane formed by all of the raised vertices of the first convex parts and the contact interface of the first substructure and the third substructure;
a side surface of the third substructure in the thickness direction has a second slope angle, the second slope angle is an included angle between the side surface of the third substructure in the thickness direction and the contact interface of the first substructure and the third substructure; and
the first slope angle and the second slope angle are both acute angles, and the first slope angle is larger than the second slope angle.

7. The mask according to claim 6, wherein,
a surface of the first shield structure on a side close to the third substructure is coplanar with a surface of the third substructure on a side close to the first substructure.

8. The mask according to claim 6, wherein,
a surface of the first shield structure on a side close to the third substructure is connected in a bonding manner with a surface of the third substructure on a side close to the first substructure.

9. The mask according to claim 1, wherein the mask satisfies one or more of the following conditions:
the metal layer comprises a magnetically attractive metal material;
the first shield structure comprises the silicon-containing material layer and the silicon-containing material layer comprises at least one of a monocrystalline silicon wafer and a silicon compound layer;
and, the second shield structure comprises the magnetically attractive metal material.

10. The mask according to claim 9, wherein,
in a case where the first shield structure comprises a magnetically attractive metal layer and a first silicon-containing material layer, the magnetically attractive metal layer is close to the process side, and the first silicon-containing material layer is away from the process side with respect to the magnetically attractive metal layer.

11. The mask according to claim 10, wherein the mask satisfies one or more of the following conditions:
the thickness of the magnetically attractive metal layer is smaller than the inner diameter of the hollows;
the thickness of the magnetically attractive metal layer is less than or equal to 10 μm;
in a case where the side surface of the first shield structure has a first slope angle, the difference between the first slope angle corresponding to the magnetically attractive metal layer and the first slope angle corresponding to the first silicon-containing material layer is less than or equal to 5°;
the first silicon-containing material layer and the second shield structure belong to different substrates;
in a case where the first silicon-containing material layer comprises a first monocrystalline silicon wafer, the thickness of the first monocrystalline silicon wafer is less than or equal to 20 μm;
and, in a case where the second shield structure comprises a second monocrystalline silicon wafer, the thickness of the second monocrystalline silicon wafer is greater than or equal to 100 μm.

12. The mask according to claim 9, wherein,
in a case where the first shield structure comprises a first substructure and the second shield structure comprises a second substructure, the second shield structure comprises a third substructure, the first substructure and the third substructure are stacked in the thickness direction;
the second substructure comprises a first monocrystalline silicon wafer, and the third substructure comprises a first silicon compound layer, a second monocrystalline silicon wafer, and a second silicon compound layer;
the first monocrystalline silicon wafer and the first silicon compound layer belong to the same substrate, and the second monocrystalline silicon wafer and the second silicon compound layer belong to the same substrate; and
the first silicon compound layer is connected with the second silicon compound layer in a bonding manner, the first monocrystalline silicon wafer is located on a side of the first silicon compound layer away from the second silicon compound layer, and the second monocrystalline silicon wafer is located on a side of the second silicon compound layer away from the first silicon compound layer.

13. The mask according to claim 12, wherein,
a side surface of the second silicon compound layer in the thickness direction are parallel to a side surface of the second monocrystalline silicon wafer in the thickness direction.

14. A preparation method of a mask, comprising:
etching a side of a substrate to obtain a plurality of grooves, wherein the substrate comprises a first region and a second region, the second region surrounds the first region, and the substrate comprises a silicon-containing material layer, wherein sidewalls of the grooves in a depth direction comprise at least one third concave part and at least one third convex part, and the third concave part is connected with the third convex part;
arranging a metal layer on a side of the substrate with the grooves, so that the grooves are filled with the metal layer; and
etching the substrate of the first region to obtain a plurality of hollows, so that the metal layer forms a first shield structure, and the substrate of the second region forms a second shield structure, wherein, an orthographic projection of the first shield structure in the first region surrounds an orthographic projection of the hollows in the first region, the first shield structure is configured to form a mask pattern, a side surface of the first shield structure in a thickness direction comprises at least one first convex part and at least one first concave part, the first convex part is connected with the first concave part, the first convex part has the same shape with the third concave part, and the first concave part has the same shape with the third convex part.

15. The preparation method of a mask according to claim 14, wherein,
the substrate comprises a monocrystalline silicon wafer;
before the etching the substrate of the first region, the preparation method further comprises:
chemically mechanical grinding the substrate on a side arranged with the metal layer to remove the metal layer between openings of the adjacent grooves, and controlling the thickness of the metal layer in the grooves to reach a given thickness;
arranging a silicon compound layer on a surface of the substrate; and
etching the silicon compound layer on a side away from the metal layer to obtain at least one first opening, wherein an orthographic projection of the first opening on the substrate covers the first region;
the etching the substrate of the first region comprises:
etching the silicon compound layer on a side close to the metal layer to obtain at least one second opening, wherein an orthographic projection of the second opening on the substrate covers the first region; and
through the first opening and the second opening, etching the substrate of the first region to obtain a plurality of hollows, so that the metal layer forms the first shield structure, and the substrate of the second region forms the second shield structure.

16. The preparation method of a mask according to claim 14, wherein,
the etching a side of the substrate to obtain a plurality of grooves comprises:
etching a side of the first substrate to obtain a plurality of grooves;
before the etching the substrate of the first region to obtain a plurality of hollows, the preparation method further comprises:
arranging a second silicon compound layer on an outer surface of the second substrate;
etching the second silicon compound layer on a side of the second substrate to obtain at least one third opening, wherein an orthographic projection of the third opening on the second substrate covers the first region; and
connecting a surface of the first substrate on a side arranged with the metal layer in a bonding manner with a surface of the second substrate on a side away from the third opening to obtain a third substrate;
the etching the substrate of the first region to obtain a plurality of hollows comprises:
chemically mechanical grinding the third substrate on a side arranged with the metal layer to remove the metal layer between openings of the adjacent grooves, and controlling the thickness of the metal layer in the grooves to reach a given thickness;
etching the first substrate outside the metal layer of the first region to obtain a plurality of first hollows, wherein the metal layer surrounds the first hollows; and
through the third opening, etching the second substrate of the first region to obtain at least one second hollow, wherein the second hollow is communicated with the first hollow, and the second hollow is in one-to-one correspondence with the third opening.

17. The preparation method of a mask according to claim 16, wherein,
before connecting a surface of the first substrate on a side arranged with the metal layer in a bonding manner with a surface of the second substrate on a side away from the third opening to obtain the third substrate, the preparation method further comprises: arranging a first silicon compound layer on an outer surface of the first substrate;
and/or,
the arranging a second silicon compound layer on an outer surface of the second substrate comprises: arranging the second silicon compound layer on a side surface of the second substrate.

18. The preparation method of a mask according to claim 14, wherein,
before the etching a side of the substrate to obtain a plurality of grooves, the preparation method further comprises: arranging a third silicon compound layer on an outer surface of the substrate;
and/or,
the arranging the metal layer comprises: arranging a seed layer; electroplating the metal layer on the seed layer.

19. The preparation method of a mask according to claim 14, wherein,
the etching a side of the substrate to obtain a plurality of grooves comprises:
performing a first etching on a side of the substrate to obtain a plurality of first grooves;
performing a first passivation treatment on the inner walls of the first grooves; and
sequentially performing a second etching treatment and a second passivation treatment of the first grooves having been performed the first passivation treatment, until a plurality of grooves with given depths are obtained, wherein the sidewalls of the grooves in the depth direction comprise at least one third concave part and at least one third convex part, and the inner diameter of the grooves corresponding to the position of the third concave part is larger than the inner diameter of the grooves corresponding to the position of the third convex part.

20. A preparation method of a mask, comprising:
arranging a metal layer on a side of a substrate, wherein the substrate comprises a first region and a second region, the second region surrounds the first region, and the substrate comprises a silicon-containing material layer;
etching the metal layer of the first region to obtain a plurality of first hollows, wherein the metal layer between the first hollows forms a first shield structure, and the first shield structure is configured to form a mask pattern; and
etching the substrate of the first region to obtain at least two second hollows, so that the second hollows are communicated with the first hollows, wherein the substrate of the second region forms a second shield structure.
